(19) United States
(12) Patent Application Publication
(10) Pub. No.: US 2026/0239702 A1
(43) Pub. Date: Aug. 13, 2026

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventor: Makoto UTSUMI, Matsumoto-city (JP)

(73) Assignee: FUJI ELECTRIC CO., LTD., Kawasaki-shi (JP)

(21) Appl. No.: 19/633,849

(22) Filed: Mar. 30, 2026

Related U.S. Application Data
(63) Continuation of application No. PCT/JP2025/005719, filed on Feb. 19, 2025.

(30) Foreign Application Priority Data
Apr. 16, 2024 (JP) 2024-066308

(51) Int. Cl. H10D 64/01; H10D 30/01; H10P 95/90

(52) U.S. Cl. CPC H10D 64/0112; H10D 30/0297; H10D 64/0115; H10P 95/90

(57) ABSTRACT

A method of manufacturing a semiconductor device, including: forming a drift layer at a surface of a semiconductor substrate; forming a plurality of source regions at a surface of the drift layer, both the drift layer and the source regions containing silicon carbide; forming a silicide layer on the source regions; forming a barrier layer containing titanium (Ti) in contact with the silicide layer; and forming a main electrode in contact with the barrier layer. The forming the silicide layer includes: forming a single layer nickel (Ni) film or a two-layer Ni and Ti film; performing a first heat treatment on the film under an inert gas atmosphere, at a temperature between 400 degrees C and 600 degrees C; removing the film unreacted after the first heat treatment; and performing a second heat treatment on the film under the inert gas atmosphere, at a temperature lower than 1000 degrees C.

### CROSS REFERENCE TO RELATED APPLICATIONS

This is a continuation application of International Application PCT/JP2025/005719 filed on February 19, 2025 which claims priority from a Japanese Patent Application No. 2024-066308 filed on April 16, 2024, the contents of which are incorporated herein by reference.

### BACKGROUND OF THE INVENTION

### 1. Field of the Invention

Embodiments of the disclosure relate to a silicon carbide semiconductor device and method of manufacturing a silicon carbide semiconductor device.

### 2. Description of the Related Art

Conventionally, to form an ohmic junction at a source region, a Ni silicide is formed on a doped region having a high concentration. To obtain favorable contact resistance, a semiconductor device has been proposed that has a structure in which contact holes are formed and thereafter, sacrificial oxidation and a hydrogen etching treatment of 1300 degrees C to 1500 degrees C are performed, Ni is deposited, and a silicide is formed under a nitrogen atmosphere of 500 degrees C to 900 degrees C. (for example, refer to Japanese Laid-Open Patent Publication No. 2023-136280).

### SUMMARY OF THE INVENTION

According to an embodiment of the present disclosure, a method of manufacturing a silicon carbide semiconductor device, the method including: preparing a semiconductor substrate; forming a drift layer of a first conductivity type, at a surface of the semiconductor substrate, the drift layer containing silicon carbide, the drift layer having a first surface and a second surface opposite to each other, the second surface facing the semiconductor substrate; forming a plurality of source regions of the first conductivity type at the first surface of the drift layer, the plurality of source regions containing silicon carbide; forming a silicide layer on the plurality of source regions; forming a barrier layer containing titanium (Ti) in contact with the silicide layer; and forming a main electrode in contact with the barrier layer. Said forming the silicide layer includes: forming a film that is a single layer nickel (Ni) film or a two-layer film including a Ni film and a Ti film, performing a first heat treatment on the film under an atmosphere of an inert gas, at a temperature of no lower than 400 degrees C but lower than 600 degrees C, removing unreacted portions of the film, and performing a second heat treatment on the film under the atmosphere containing the inert gas, at a temperature lower than 1000 degrees C.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting an active region of a silicon carbide semiconductor device according to an embodiment.

FIG. 2 is a schematic diagram of a contact hole of the silicon carbide semiconductor device according to the embodiment.

FIG. 3 is a flowchart of silicide layer formation in a method of manufacturing the silicon carbide semiconductor device according to the embodiment.

FIG. 4 is a graph depicting dependence of sheet resistance on a temperature of a first silicidation annealing, after the first silicidation annealing.

FIG. 5 is a graph depicting the dependence of sheet resistance on the temperature of the first silicidation annealing, after a second silicidation annealing.

FIG. 6 is a graph depicting the dependence of sheet resistance on the temperature of the second silicidation annealing, after the second silicidation annealing.

FIG. 7 is a graph depicting Raman spectrum after the first silicidation annealing.

FIG. 8 is a graph depicting Raman spectrum after the first silicidation annealing.

FIG. 9 is a schematic diagram of a SEM image of a cross-section after the second silicidation annealing.

FIG. 10 is a schematic diagram of a SEM image of a cross-section after the second silicidation annealing.

FIG. 11 is a schematic diagram of a SEM image of a cross-section after the second silicidation annealing.

FIG. 12 is a schematic diagram of a SEM image of a cross-section after the second silicidation annealing.

FIG. 13 is a schematic diagram of a SEM image of a cross-section after the second silicidation annealing.

FIG. 14 is a schematic diagram of a SEM image of a cross-section after the second silicidation annealing.

FIG. 15 is a flowchart depicting conventional silicide layer formation.

FIG. 16 is a schematic diagram of contact holes of a conventional silicon carbide semiconductor device.

### DETAILED DESCRIPTION OF THE INVENTION

First, problems associated with the conventional techniques are discussed. In the conventional semiconductor device, a problem arises in that the Ni silicide is not formed uniformly and contact resistance increases.

Here, an outline of an embodiment of the present disclosure is described. A silicon carbide semiconductor device according to the present disclosure has the following features. The silicon carbide semiconductor device has a drift layer of a first conductivity type, containing silicon carbide; source regions of the first conductivity type, containing silicon carbide and provided at a surface of the drift layer; a silicide layer provided on the source regions; a barrier layer containing titanium (Ti) and in contact with the silicide layer; and a main electrode provided in contact with the barrier layer. The barrier layer is free of a portion that is in contact with the source regions.

According to the disclosure above, the silicide layer is formed uniformly, whereby no areas where the silicon carbide layer and the barrier metal are in direct contact with each other are formed, whereby the contact resistance may be reduced.

Further, in the silicon carbide semiconductor device according to the present disclosure, in the disclosure above, a height difference of the silicide layer is not more than 40 nm.

A method of manufacturing a silicon carbide semiconductor device according to the present disclosure has the following features. First, as a first process, a drift layer of a first conductivity type and containing silicon carbide is formed. Next, as a second process, source regions of the first conductivity type and containing silicon carbide are formed at a surface of the drift layer. Next, as a third process, a silicide layer is formed on the source regions. Next, as a fourth process, a barrier layer in contact with the silicide layer and containing titanium (Ti) is formed. Next, as a fifth process, a main electrode in contact with the barrier layer is formed. The third process includes: as a sixth process, forming a film containing nickel (Ni) or Ni and Ti; as a seventh process, performing a first heat treatment on the film under an inert gas (group 18) atmosphere, at a temperature of 400 degrees C or higher but less than 600 degrees C; as an eighth process, removing the film that is unreacted by the first heat treatment of the seventh process; and as a ninth process, performing a second heat treatment on the film under the inert gas (group 18) atmosphere, at a temperature less than 1000 degrees C.

Further, in the method of manufacturing the silicon carbide semiconductor device according to the present disclosure, in the disclosure above, in the ninth process, the temperature of the second heat treatment is 900 degrees C or higher but less than 1000 degrees C.

Further, in the method of manufacturing the silicon carbide semiconductor device according to the present disclosure, in the disclosure above, when the film contains Ni, the temperature of the first heat treatment is 450 degrees C or higher but less than 600 degrees C in the seventh process.

Further, in the method of manufacturing the silicon carbide semiconductor device according to the present disclosure, in the disclosure above, when the film contains Ni and Ti, the temperature of the first heat treatment is 400 degrees C or higher but less than 500 degrees C in the seventh process.

Further, in the method of manufacturing the silicon carbide semiconductor device according to the present disclosure, in the disclosure above, the inert gas (group 18) is any one of helium (He), neon (Ne), argon (Ar), krypton (Kr), and xenon (Xe).

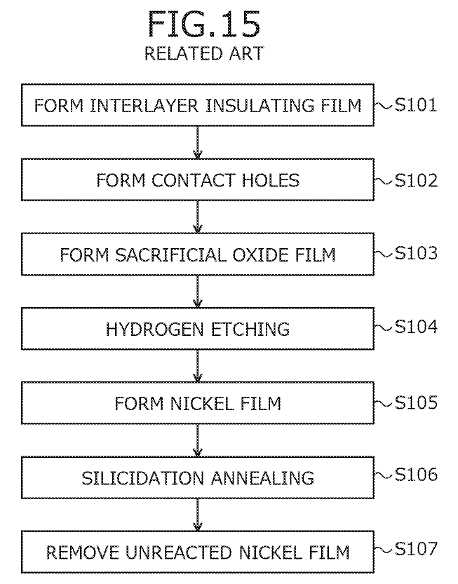

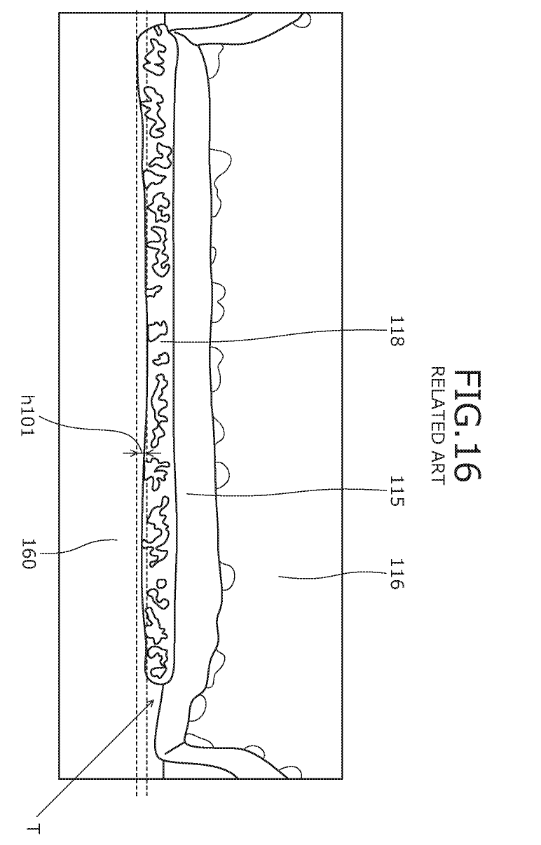

Here, findings underlying the present disclosure are discussed. First, problems associated with a method of manufacturing the conventional silicon carbide semiconductor device are discussed. Conventionally, to obtain favorable contact resistance, contact holes are formed and thereafter, sacrificial oxidation and a hydrogen etching treatment of 1300 degrees C to 1500 degrees C are performed, Ni(nickel) is deposited, and a silicide is formed under a nitrogen atmosphere of 500 degrees C to 900 degrees C. FIG. 15 is a flowchart of conventional silicide layer formation. As depicted in FIG. 15, first, an interlayer insulating film is formed on a silicon carbide layer (step S101). Next, contact holes are formed in the interlayer insulating film (step S102). Next, sacrificial oxidation is performed on the silicon carbide layer thereby forming a sacrificial oxide film (step S103). The sacrificial oxidation is thermal oxidation and by forming the sacrificial oxide film, damage and impurities at the surface of the silicon carbide layer are removed.

Next, under an atmosphere containing hydrogen (H₂), the surface of the silicon carbide layer is etched at a temperature in a range of 1300 degrees C to 1500 degrees C (step S104). As a result, the amount of carbon vacancies of the silicon carbide layer is reduced. Next, a nickel film is formed in the contact holes (step S105). Next, under an atmosphere containing nitrogen gas, silicidation annealing is performed at a temperature in a range of 500 degrees C to 900 degrees C (step S106). Finally, portions of the nickel film removed (step S107).

As described, nickel diffuses to the target side and favorable contact resistance is obtained by the effects of removing damage and impurities at the surface of the silicon carbide layer by sacrificial oxidation and reducing the amount of carbon vacancies by hydrogen etching.

However, although the process of forming the Ni silicide is performed after the formation of the interlayer insulating film containing NSG or BPSG and thereafter, an electrode pad such as an Al electrode is formed functioning as a contact electrode, the sacrificial oxidation and hydrogen etching, which affect the shape, are difficult to perform after the interlayer insulating film is formed.

Thus, it is conceivable to form the Ni silicide by forming a nickel film, performing silicidation annealing (500 degrees C, N2 atmosphere), removing the unreacted nickel film, and performing silicidation annealing (950 degrees C, N2 atmosphere), without using sacrificial oxidation or hydrogen etching. FIG. 16 is a schematic diagram of contact holes of a conventional silicon carbide semiconductor device. As depicted in FIG. 16, on a silicon carbide layer 160, a silicide layer 118, a barrier metal 115, and a source electrode 116 are sequentially stacked in the order stated.

In an instance of formation by this method, there is an area (in the drawing, “T”) where the silicide layer 118 is not formed by the silicidation annealing and the silicon carbide layer 160 and the barrier metal 115 are in direct contact with each other. Furthermore, a height difference h101 of the silicide layer 118 with respect to the silicon carbide layer 160 is greater than 50 nm; there are only 1 to 2 locations at a same depth as the deepest point; and the silicide layer 118 is not uniformly formed.

In a semiconductor chip, one reason for the high contact resistance is the formation of an area where the silicon carbide layer and the electrode pad are in direct contact with each other due to the non-uniform formation of Ni silicide. Thus, the challenge is to establish a process for forming Ni silicide, a process that does not use sacrificial oxidation or hydrogen etching and that is less likely to cause variations within the wafer surface or between lots.

Embodiments of a silicon carbide semiconductor device and a method of manufacturing a silicon carbide semiconductor device according to the present disclosure will be described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -. In the description of the embodiments below and the accompanying drawings, main portions that are identical will be given the same reference numerals and will not be repeatedly described. Further, with consideration of variation in manufacturing, description indicating the same or equal may be within 5%.

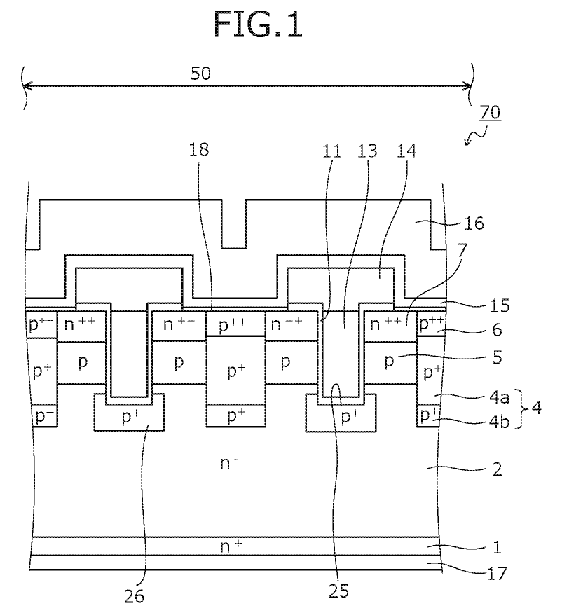

A semiconductor device according to the present disclosure is configured using a wide band gap semiconductor. In the embodiment, a silicon carbide semiconductor device fabricated using for example, silicon carbide (SiC) as a wide band gap semiconductor is described taking a metal oxide semiconductor field effect transistor (MOSFET) as an example. FIG. 1 is a cross-sectional view depicting an active region of a silicon carbide semiconductor device according to the embodiment.

A silicon carbide semiconductor device 70 according to the embodiment has a semiconductor substrate that contains silicon carbide (hereinafter, silicon carbide substrate (semiconductor chip)) and has an active region 50 and an edge termination region (not depicted) surrounding a periphery of the active region 50 in a plan view. The active region 50 is a region through with current flows during an on-state. The edge termination region is a region that relaxes electric field of a front side of a drift region and sustains a breakdown voltage.

As depicted in FIG. 1, the silicon carbide substrate has an n⁺-type starting substrate (n⁺-type silicon carbide substrate) 1 containing silicon carbide; an n⁻-type drift region (drift layer of a first conductivity type) 2, containing silicon carbide on a front surface of the n⁺-type starting substrate 1; and a p-type base region 5 containing silicon carbide at a first surface of the n⁻-type drift region 2 opposite to a second surface thereof facing the n⁺-type silicon carbide substrate 1. The n⁺-type silicon carbide substrate 1 functions as a drain region. Further, between the n⁻-type drift region 2 and the n⁺-type silicon carbide substrate 1, for example, a buffer layer or the like that reduces the growth of crystal defects from the n⁺-type silicon carbide substrate 1 may be provided.

The n+-type silicon carbide substrate 1 is a silicon carbide single crystal substrate. The n--type drift region 2 has a dopant concentration that is lower than a dopant concentration of the n+-type silicon carbide substrate 1. The n--type drift region 2 extends to the p-type base region 5, is in contact with the p-type base region 5 and later-described p+-type regions 4, extends to later-described trenches 25 in a direction parallel to the front surface of the semiconductor substrate, and is in contact with gate insulating films 11. The n--type drift region 2 has, for example, a dopant concentration that is not more than 5×1016cm-3 and a thickness that is 5.0 μm or greater.

Further, between the n--type drift region 2 and the p-type base region 5, n-type high-concentration regions (not depicted) may be provided. In an instance in which the n-type high-concentration regions are provided, the later-described p+-type regions 4 that are adjacent to each other are in contact with these regions, extend in a direction parallel to the front surface of the semiconductor substrate to the trenches 25 and are in contact with the gate insulating films 11. The n-type high-concentration regions each have an upper surface in contact with the p-type base region 5 and a lower surface in contact with the n--type drift region 2. A dopant concentration of the n-type high-concentration regions is lower than that of the n+-type silicon carbide substrate 1 but higher than that of the n--type drift region 2.

At a second main surface (back surface, i.e., back surface of the silicon carbide substrate) of the n+-type silicon carbide substrate 1, a drain electrode 17 constituting a back electrode is provided. At the surface of the drain electrode 17, an electrode pad (not depicted) is provided.

In the silicon carbide substrate, at a first main surface thereof (side having the p-type base region 5), a trench structure is formed. In particular, the trenches 25 penetrate through the p-type base region 5 from a first surface (front side of the silicon carbide substrate) of the p-type base region 5, opposite to a second surface thereof facing the n+-type silicon carbide substrate 1, and extend to the n--type drift region 2 (in an instance in which the n-type high-concentration regions are provided, the n-type high-concentration regions).

The gate insulating films 11 are formed, respectively, along inner walls of the trenches 25, at bottoms and sidewalls of the trenches 25, and gate electrodes 13 are formed, respectively, on the gate insulating films 11 in the trenches 25. The gate insulating films 11 insulate the gate electrodes 13 from the n--type drift region 2 and the p-type base region 5. A portion of each of the gate electrodes 13 may protrude from tops (side facing a later-described source electrode 16) of the trenches 25 in a direction toward the source electrode 16.

In the n--type drift region 2, at the first surface thereof (front side of the silicon carbide substrate), opposite to the second surface thereof facing the n+-type silicon carbide substrate 1, upper p+-type regions 4a are provided. The upper p+-type regions 4a, for example, are provided between the trenches 25. Further, in the n--type drift region 2, lower p+-type regions 4b respectively in contact with the upper p+-type regions 4a are provided. Further, at the bottoms of the trenches 25, p+-type regions 26 are provided, respectively. The p+-type regions 26, which are in contact with the bottoms of the trenches 25, respectively, are provided at positions facing the bottoms of the trenches 25 in a depth direction (direction from the source electrode 16 to the back electrode). Between the trenches 25, the upper p+-type regions 4a and the lower p+-type regions 4b adjacent thereto combined constitute the p+-type regions 4

A width of each of the p+-type regions 26 is a same width as or wider than a width of each of the trenches 25. Further, a width of each of the lower p+-type regions 4b is a same width as or wider than a width of each of the upper p+-type regions 4a. The bottoms of the trenches 25 may extend to the p+-type regions 26 or may be positioned in the n--type drift region 2, between the p-type base region 5 and the p+-type regions 26.

In the p-type base region 5, in the silicon carbide substrate, at the first main surface thereof, n++-type source regions (source regions of the first conductivity type) 7 and p++-type contact regions 6 are selectively provided. Further, the n++-type source regions 7 and the p++-type contact regions 6 are in contact with each other.

An interlayer insulating film 14 is provided in an entire area of the first main surface of the silicon carbide substrate so as to cover the gate electrodes 13 embedded in the trenches 25. The interlayer insulating film 14 contains NSG or BPSG. In the interlayer insulating film 14, contact holes are opened and at bottoms of the contact holes, a silicide layer 18 in contact with the n⁺⁺-type source regions 7 and the p⁺⁺-type contact regions 6 is provided. The source electrode 16 is in contact with the n⁺⁺-type source regions 7 and the p⁺⁺-type contact regions 6 via the silicide layer 18. The source electrode (main electrode) 16 is electrically insulated from the gate electrodes 13 by the interlayer insulating film 14. Above the source electrode 16, a source electrode pad (not depicted) is provided. Between the source electrode 16 and the interlayer insulating film 14, for example, a barrier metal (barrier layer) 15 that prevents metal atoms from diffusing from the source electrode 16 to the gate electrodes 13 is provided. A polyimide (not depicted) that functions as a protective film is provided at the surface of the silicon carbide semiconductor device 70. In FIG. 1, while only two MOS gate (metal-oxide-semiconductor insulated gate) structures are depicted in the active region 50, numerous MOS gate structures may be further provided in parallel.

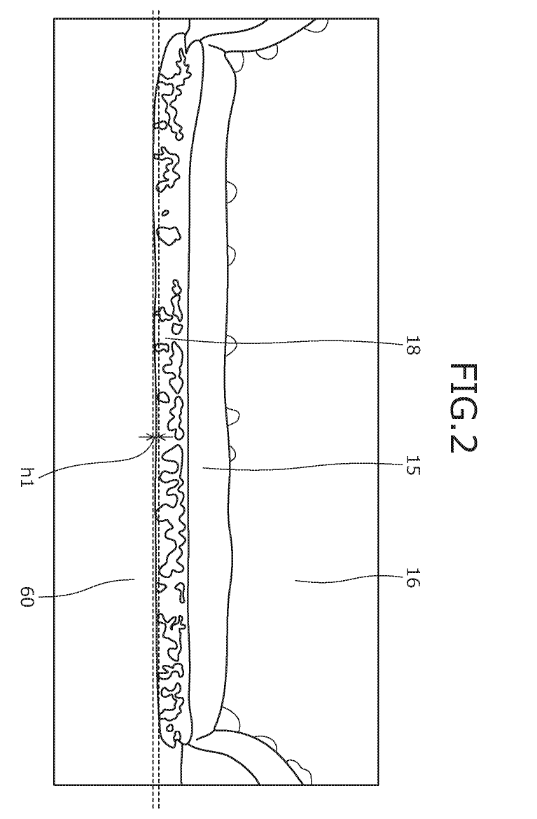

FIG. 2 is a schematic diagram of a contact hole of the silicon carbide semiconductor device according to the embodiment. In the embodiment, the silicide layer 18 is formed by a later-described method of manufacturing. Thus, as depicted in FIG. 2, the silicide layer 18 is formed uniformly. For example, by a silicidation annealing, there is no area lacking the silicide layer 18 and no area where a silicon carbide layer 60 and the barrier metal 15 are in direct contact with each other. The silicon carbide layer 60 is, for example, a region including the n++-type source regions 7, the p++-type contact regions 6, and the p-type base region 5. Further, a height difference h1 of the silicide layer 18 with respect to the silicon carbide layer 60 is less than 40 nm and there are three or more locations at a same depth as the deepest point. The height difference h1 at a surface of the silicide layer 18 (said surface thereof facing the silicon carbide layer 60) is a difference of a location farthest from to the silicon carbide layer 60 and a location closest to the silicon carbide layer 60. The deepest point is a portion of the surface of the silicide layer 18 (said surface facing the silicon carbide layer 60) closest to the silicon carbide layer 60. As described, in the embodiment, the silicide layer 18 is formed uniformly without the formation of an area where the silicon carbide layer 60 and the barrier metal 15 are in direct contact with each other, enabling reduction of the contact resistance.

Next, a method of manufacturing the silicon carbide semiconductor device according to the embodiment is described. For example, the silicon carbide semiconductor device is manufactured as follows. First, at the front surface of the n+-type silicon carbide substrate 1, the n--type drift region 2 is grown by epitaxy (first process).

Next, at a front surface of the n--type drift region 2, the p-type base region 5 is grown by epitaxy. The p-type base region 5 may be formed by ion implantation. Between the n--type drift region 2 and the p-type base region 5, n-type high-concentration regions may be formed.

Next, by photolithography and ion implantation of a p-type dopant, p-type regions (the p+-type regions 4, the p++-type contact regions 6, the p+-type regions 26) are formed and by photolithography and ion implantation of an n-type dopant, the n++-type source regions 7 are formed (second process). Next, a heat treatment for activating dopants ion-implanted in the n--type drift region 2 and the p-type base region 5 is performed. The heat treatment for dopant activation may be performed each time a dopant is ion-implanted or may be performed for the regions collectively. Next, by a general method, the trenches 25, the gate insulating films 11, and the gate electrodes 13 are formed.

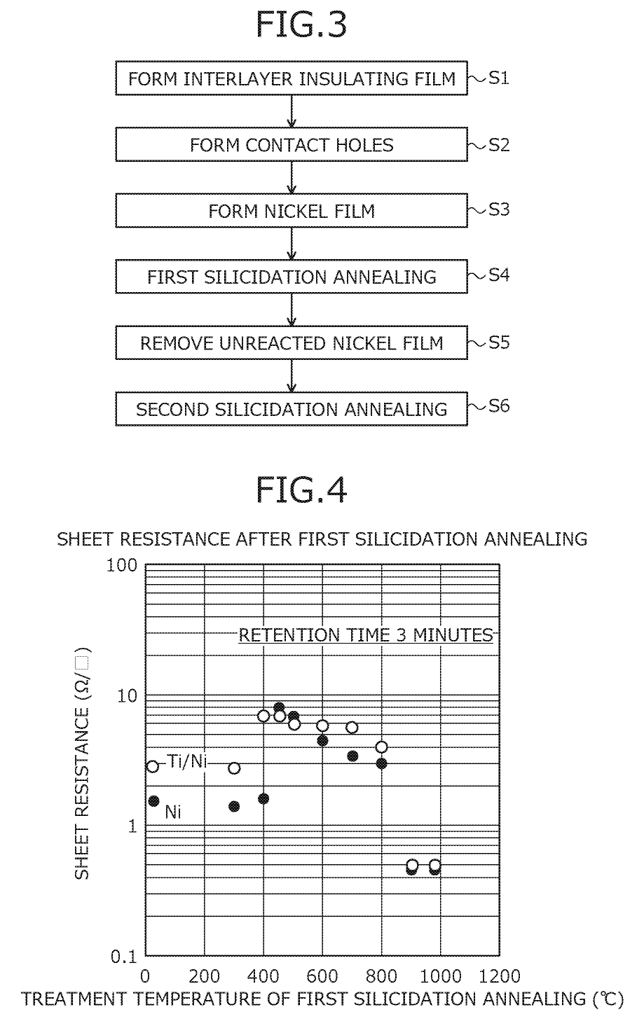

Next, the p-type base region 5, the silicide layer 18 is formed on the p++-type contact regions 6 and the n++-type source regions 7 (third process). Hereinafter, a method of forming the silicide layer 18 is described in detail. FIG. 3 is a flowchart of silicide layer formation in the method of manufacturing the silicon carbide semiconductor device according to the embodiment. As depicted in FIG. 3, first, the interlayer insulating film 14 is formed on the silicon carbide layer 60 (step S1). Next, contact holes are formed in the interlayer insulating film 14 (step S2). Next, a nickel film is formed in the contact holes (step S3, sixth process). Here, while a nickel film is formed, a stacked film of nickel and titanium (Ti) films or a mixture of Ni and Ti is possible. With a mixture of Ti, the heat treatment (annealing) may be performed at a low temperature. In an instance of a stacked film of Ni and Ti films, Ti is formed on the silicon carbide layer 60 so that TiC is formed.

Next, under an inert gas (group 18 (helium (He), neon (Ne), argon (Ar), krypton (Kr), or xenon (Xe)) atmosphere, at a temperature less than 600 degrees C, for example, 400 degrees C or higher but less than 600 degrees C, a first silicidation annealing is performed (step S4, seventh process). In an instance of Ni, preferably, the temperature may be 450 degrees or higher but less than 600 degrees C and in an instance of Ni and Ti, the temperature may be 400 degrees or higher but less than 500 degrees C. Next, unreacted portions of the nickel film removed (step S5, eighth process). Preferably, the removal may be performed, for example, by wet etching. Preferably, the wet etching may be performed using phosphoric acid + nitric acid + acetic acid.

Finally, again, under an inert gas (group 18 (He, Ne, Ar, Kr, or Xe)) atmosphere, at a temperature lower than a reflow temperature (1000 degrees C) of BPSG, for example, 900 degrees C or higher by less than 1000 degrees C, a second silicidation annealing is performed as a heat treatment for silicide conversion by a solid-state reaction (step S6, ninth process). The second silicidation annealing advances the silicide reaction, thereby forming ohmic electrodes.

Here, heating by a temperature lower than the reflow temperature for BPSG may prevent Ni from penetrating into the BPSG, suppress formation of a barrier (inhibition) layer, and define a region where the silicide layer 18 will form. Further, the heat treatment is performed under an inert gas (group 18 (He, Ne, Ar, Kr, or Xe)) atmosphere, whereby the formation of a reaction inhibition layer (SiN) of the silicon carbide layer 60 may be prevented and the silicide may be formed uniformly. By performing the formation processes described, uneven formation is prevented and the silicide layer 18 may be formed uniformly. Thus, without the formation of areas where the silicon carbide layer 60 and the barrier metal 15 are in direct contact with each other, the contact resistance may be reduced.

Next, in the contact holes and at the surface of the interlayer insulating film 14, a Ti film is uniformly deposited by sputtering. Next, at the surface of the Ti film, a TiN film is formed by sputtering. As a result, the barrier metal 15 is stacked on the interlayer insulating film 14 and in the contact holes (the fourth process). Next, the Ti film at the bottoms of the contact holes is silicidated by a heat treatment (annealing). Next, an Al metal film constituting the source electrode 16 is, for example, deposited by sputtering. The Al metal film may be formed using, for example, aluminum containing 1% silicon (Al-Si). Next, the Al metal film is patterned thereby forming the source electrode 16 (fifth process). Thereafter, by a general method, a gate pad (not depicted), a passivation film (surface-protecting film: not depicted) and the drain electrode 17 are formed. A portion of the source electrode 16 exposed in an opening of the passivation film constitutes a source pad. Thereafter, the semiconductor wafer is diced (cut) into individual chips, whereby the silicon carbide semiconductor device 70 depicted in FIG. 1 is completed.

Next, an Al metal film constituting the source electrode 16 is, for example, deposited by sputtering. The Al metal film may be formed using, for example, aluminum containing 1% silicon (Al-Si). Next, the Al metal film is patterned thereby forming the source electrode 16 (fifth process). Thereafter, by a general method, a gate pad (not depicted), a passivation film (surface-protecting film: not depicted) and the drain electrode 17 are formed. A portion of the source electrode 16 exposed in an opening of the passivation film constitutes a source pad. Thereafter, the semiconductor wafer is diced (cut) into individual chips, whereby the silicon carbide semiconductor device 70 depicted in FIG. 1 is completed.

FIG. 4 is a graph depicting the dependence of sheet resistance on the temperature of the first silicidation annealing, after the first silicidation annealing. In FIG. 4, a horizontal axis indicates the treatment temperature of the first silicidation annealing in units of degrees C. A vertical axis indicates sheet resistance in units of Ω/□. FIG. 4 depicts sheet resistance after the first silicidation annealing in instances in which an Ni film and a stacked Ni/Ti film are respectively formed and the treatment temperature of the first silicidation annealing is varied.

The results for the Ni film were obtained by forming the Ni film to have a thickness of 50 nm to 100 nm using sputtering equipment and performing a heat treatment using vertical treatment equipment. The results for the Ni/Ti were obtained by forming a Ti film having a thickness of 25 nm to 50 nm and an Ni film having a thickness of 25 nm to 50 nm (fabricated with a 1:1 thickness) using sputtering equipment and performing a heat treatment using vertical treatment equipment.

As depicted in FIG. 4, it was found that in the case of the Ni film, when the treatment temperature of the first silicidation annealing was 25 degrees C to 400 degrees C, the sheet resistance was the same as that after the Ni film was formed and the Ni film was unreacted and not silicidated; and at 450 degrees C to 800 degrees C, the sheet resistance increased sharply, silicidation progressed and a reaction layer was formed; and at 900 degrees C or higher, the sheet resistance decreased and the Ni film was sufficiently silicidated.

Further, it was found that in the case of the stacked Ni/Ti film, when the treatment temperature of the first silicidation annealing was 25 degrees C to 350 degrees C, the sheet resistance was the same as that after the stacked Ni/Ti film was formed and the stacked Ni/Ti film was unreacted and not silicidated; and at 450 degrees C to 800 degrees C, the sheet resistance increased sharply, silicidation progressed and a reaction layer was formed; and at 900 degrees C or higher, the sheet resistance decreased and the Ni film was sufficiently silicidated.

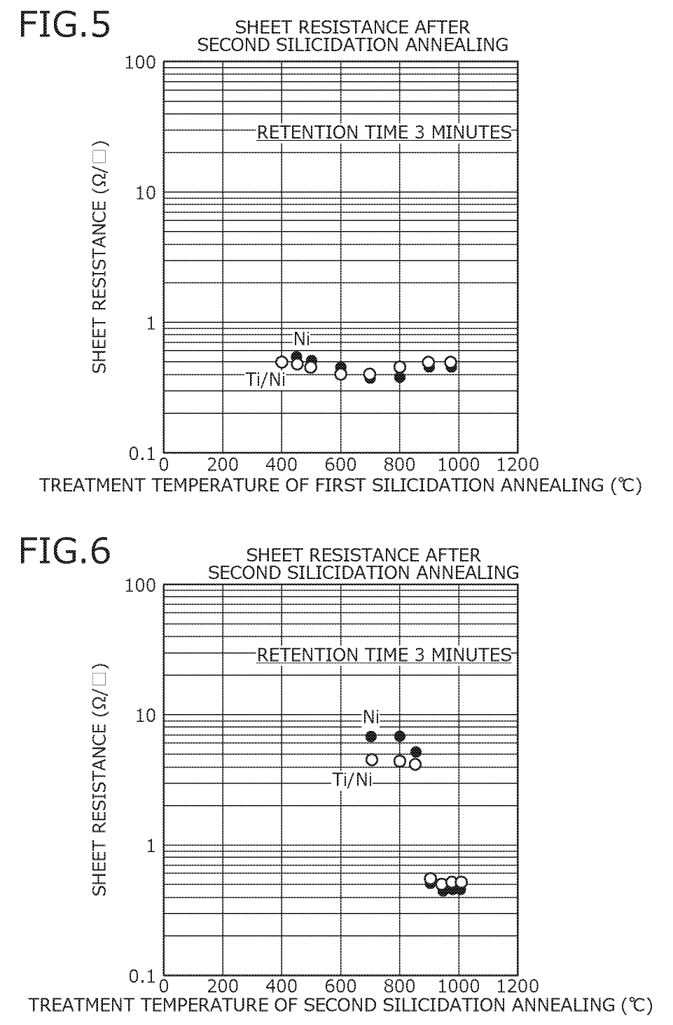

FIG. 5 is a graph depicting the dependence of sheet resistance on the temperature of the first silicidation annealing, after the second silicidation annealing. In FIG. 5, a horizontal axis indicates the treatment temperature of the first silicidation annealing in units of degrees C. A vertical axis indicates sheet resistance in units of Ω/□. FIG. 5 depicts sheet resistance after the second silicidation annealing in instances in which an Ni film and a stacked Ni/Ti film are respectively formed and the treatment temperature of the first silicidation annealing is varied. Deposition conditions are the same as those in the case of FIG. 4. The results depicted were obtained when the second silicidation annealing was performed at 975 degrees C.

As depicted in FIG. 5, for both the Ni film and the stacked Ni/Ti film, when the second silicidation annealing is performed at 975 degrees C, regardless of the treatment temperature of the first silicidation annealing, the sheet resistance decreases and silicidation is sufficient.

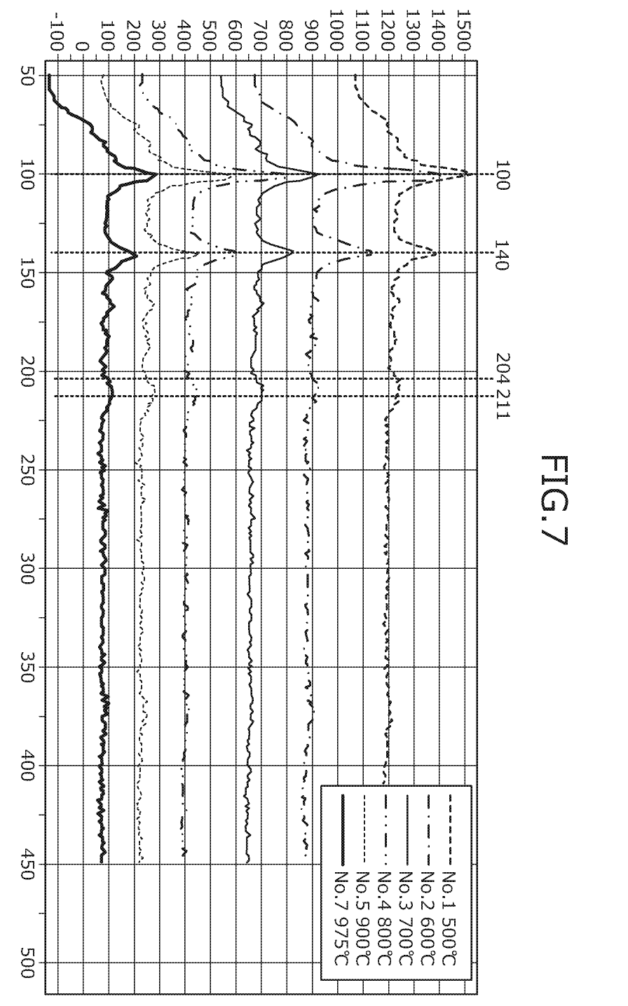

FIG. 6 is a graph depicting the dependence of sheet resistance on the temperature of the second silicidation annealing, after the second silicidation annealing. In FIG. 6, a horizontal axis indicates the treatment temperature of the second silicidation annealing in units of degrees C. A vertical axis indicates sheet resistance in units of Ω/□. FIG. 6 depicts sheet resistance after the second silicidation annealing in instances in which an Ni film and a stacked Ni/Ti film are respectively formed and the treatment temperature of the first silicidation annealing is 500 degrees C and the treatment temperature of the second silicidation annealing is varied.

In FIG. 6, composition of the BPSG is phosphorus (P) 3.7 wt%, boron (B) 8.1 wt%, silicon (Si) 88.2 wt%, and oxygen (O) residue (P2O5 2 mol%, B2O3 6.5 mol%)

As depicted in FIG. 6, for both the Ni film and the stacked Ni/Ti film, when the treatment temperature of the second silicidation annealing is 900 degrees C or higher, the sheet resistance decreases and silicidation is sufficient. Thus, a lower limit of the second silicidation annealing is 900 degrees C and an upper limit is 1000 degrees C (reflow temperature of BPSG).

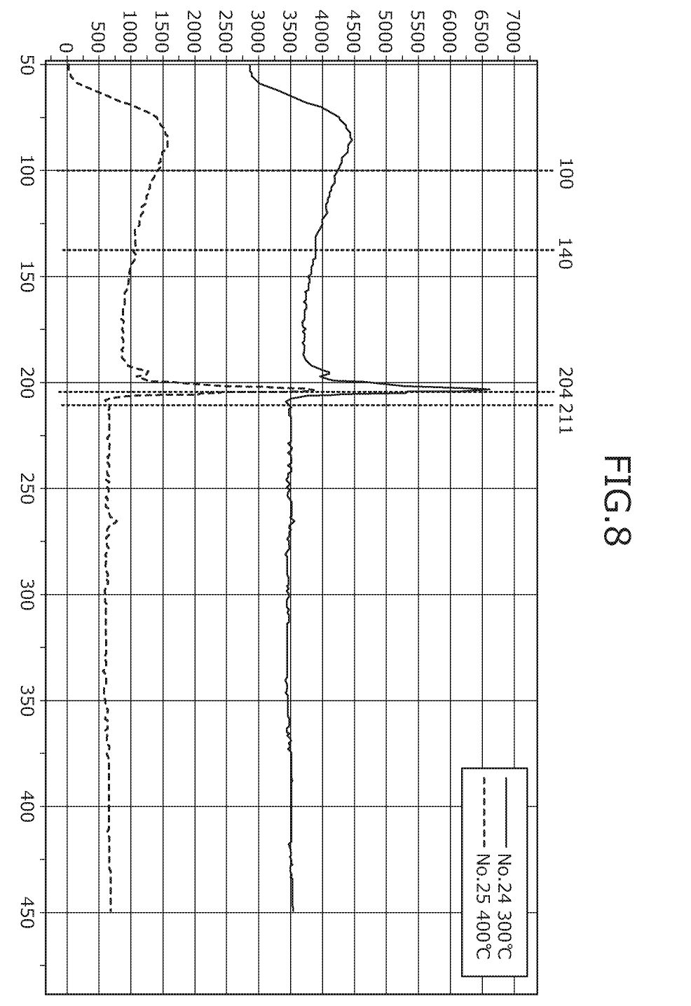

FIGS. 7 and 8 are graphs depicting Raman spectrum after the first silicidation annealing. FIGS. 7 and 8 depict the Raman spectrum when an Ni film is formed and the treatment temperature of the first silicidation annealing is changed. In FIGS. 7 and 8, a horizontal axis indicates Raman shift in units of cm-1. A vertical axis indicates spectral intensity in an arbitrary unit. In FIGS. 7 and 8, Raman shift 100 cm-1 and 140 cm-1 represent the spectrum of Ni2Si, 211 cm-1 represents the spectrum of NiSi, and 204 cm-1 represents the spectrum of SiC. As depicted in FIGS. 7 and 8, it was found that when the treatment temperature of the first silicidation annealing is set to 500 degrees C or higher, a silicide is formed.

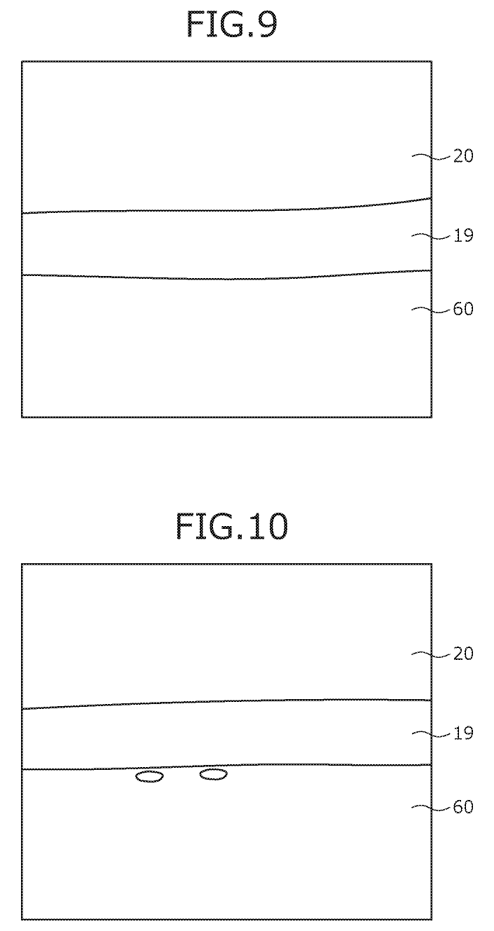

FIGS. 9, 10, 11, 12, 13 and 14 are schematic diagrams of SEM images of a cross-section after the second silicidation annealing. FIGS. 9 to 14 are scanning electron microscope (SEM) images of samples coated with platinum films 19, 20.

As depicted in FIG. 9, when the treatment temperature of the first silicidation annealing was 300 degrees C and the treatment temperature of the second silicidation annealing was 975 degrees C, the silicide layer 18 (Ni silicide) was not detected.

As depicted in FIG. 10, when the treatment temperature of the first silicidation annealing was 400 degrees C and the treatment temperature of the second silicidation annealing was 975 degrees C, the silicide layer 18 (Ni silicide) was not detected.

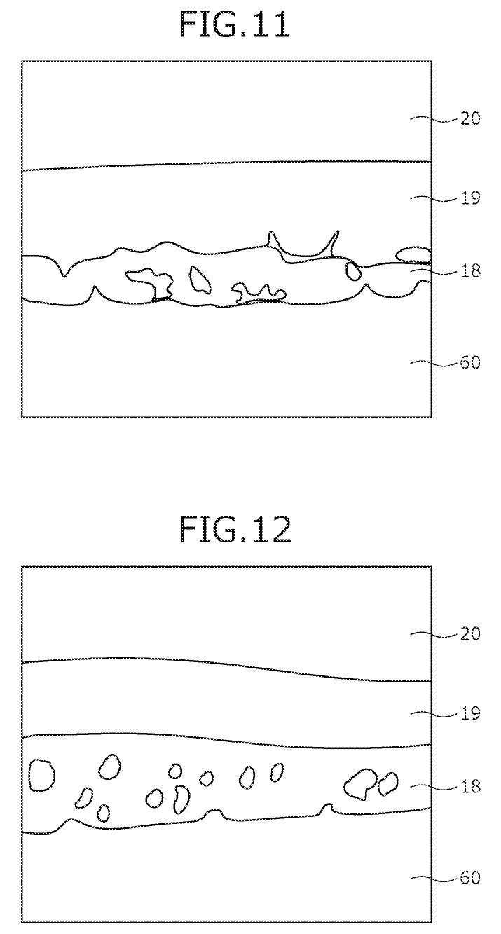

As depicted in FIG. 11, when the treatment temperature of the first silicidation annealing was 500 degrees C and the treatment temperature of the second silicidation annealing was 975 degrees C, the silicide layer 18 (Ni silicide) was detected.

As depicted in FIG. 12, when the treatment temperature of the first silicidation annealing was 600 degrees C and the treatment temperature of the second silicidation annealing was 975 degrees C, the silicide layer 18 (Ni silicide) was detected.

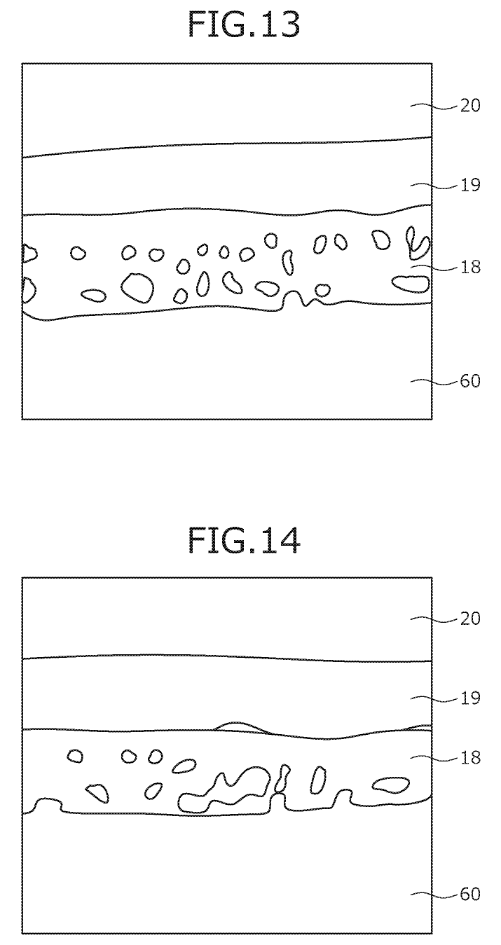

As depicted in FIG. 13, when the treatment temperature of the first silicidation annealing was 900 degrees C and the treatment temperature of the second silicidation annealing was 975 degrees C, the silicide layer 18 (Ni silicide) was detected.

As depicted in FIG. 14, when silicidation annealing was performed once at a treatment temperature of 900 degrees C, the silicide layer 18 (Ni silicide) was detected.

As depicted in FIGS. 9 to 14, it was found that when the treatment temperature of the first silicidation annealing was 500 degrees C or higher and the treatment temperature of the second silicidation annealing was 975 degrees C, the silicide layer 18 (Ni silicide) was formed.

As described, according to the embodiments, a nickel film is formed and thereafter, the first silicidation annealing is performed under an inert gas (group 18) atmosphere, at a temperature less than 600 degrees C, unreacted portions of the nickel film removed and thereafter, the second silicidation annealing is performed under an inert gas (group 18) atmosphere, at a temperature less than 1000 degrees C. As a result, uneven formation is prevented and the silicide layer may be formed uniformly. Thus, contact resistance may be reduced without the formation of areas where the silicon carbide layer and the barrier metal are in direct contact with each other.

In the foregoing, various modifications within a range not departing from the scope of the present disclosure a possible and, for example, in the embodiments, dimensions, dopant concentrations, etc. of regions and like may be variously set according to necessary specifications. Further, in the embodiments, while the first conductivity type is assumed to be an n-type and a second conductivity type is assumed to be a p-type, the present disclosure is similarly implemented when the first conductivity type is a p-type and the second conductivity type is an n-type.

According to the disclosure above, the silicide layer is formed uniformly and thus, the contact resistance may be reduced without the formation of areas where the silicon carbide layer and the barrier metal are in direct contact with each other.

The silicon carbide semiconductor device according to the present disclosure and the method of manufacturing a silicon carbide semiconductor device achieve an effect in that uneven formation of Ni silicide is prevented and the contact resistance may be reduced.

As described, the semiconductor device according to the present disclosure and the method of manufacturing a silicon carbide semiconductor device are useful for power semiconductor devices used in power converting equipment such as inverters, power source devices such as those of various types of industrial machines, automotive igniters, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a silicon carbide semiconductor device, the method comprising:
preparing a semiconductor substrate;
forming a drift layer of a first conductivity type, at a surface of the semiconductor substrate, the drift layer made of silicon carbide, the drift layer having a first surface and a second surface opposite to each other, the second surface facing the semiconductor substrate;
forming a plurality of source regions of the first conductivity type at the first surface of the drift layer, the plurality of source regions containing silicon carbide;
forming a silicide layer on the plurality of source regions;
forming a barrier layer containing titanium (Ti) in contact with the silicide layer; and
forming a main electrode in contact with the barrier layer, wherein
said forming the silicide layer includes:
forming a film that is a single layer nickel (Ni) film or a two-layer film including a Ni film and a Ti film,
performing a first heat treatment on the film under an atmosphere of an inert gas, at a temperature of no lower than 400 degrees C but lower than 600 degrees C,
removing unreacted portions of the film, and
performing a second heat treatment on the film under the atmosphere containing the inert gas, at a temperature lower than 1000 degrees C.

2. The method according to claim 1, wherein the temperature of the second heat treatment is no lower than 900 degrees C.

3. The method according to claim 1, wherein the temperature of the first heat treatment is no lower than 450 degrees C, when the single layer Ni film is formed as the film.

4. The method according to claim 1, wherein the temperature of the first heat treatment is lower than 500 degrees C, when the two-layer film is formed as the film.

5. The method according to claim 1, wherein the inert gas is any one of helium, neon, argon, krypton, and xenon.
